(19) United States
(12) Patent Application Publication
(10) Pub. No.: US 2005/0012207 A1
(43) Pub. Date: Jan. 20, 2005

(54) Substrate structure for an integrated circuit package and method for manufacturing the same

(76) Inventors: Jackson Hsieh, Hsinchu Hsien (TW); Jichen Wu, Hsinchu Hsien (TW)

Correspondence Address: PRO-TECHTOR INTERNATIONAL, 20775 Norada Court, Saratoga, CA, 95070-3018, US

(21) Appl. No.: 10/621,987

(22) Filed: Jul. 16, 2003

(51) Int. Cl. H01L 23/06

(52) U.S. Cl. 257/729

(57) ABSTRACT

A substrate structure for an integrated circuit package to be electrically connected to a printed circuit board. The substrate structure includes a plurality of lower metal sheets arranged in an array, a plurality of upper metal sheets arranged in an array, and an encapsulant for encapsulating the lower metal sheets and the upper metal sheets. Each of the lower metal sheets has an upper surface and a lower surface. Each of the upper metal sheets has an upper surface and a lower surface, and the lower surfaces of the upper metal sheets are stacked on the upper surfaces of the lower metal sheets. The upper surfaces of the upper metal sheets are exposed from the encapsulant, and the lower surfaces of the lower metal sheets are exposed from the encapsulant and electrically connected to the printed circuit board.

### BACKGROUND OF THE INVENTION

1. Field of the Invention

The invention relates to a substrate structure for an integrated circuit package and a method for manufacturing the same, and more particularly to a substrate structure for an integrated circuit package with enhanced product reliability and increased adhesion forces during the SMT process.

2. Description of the Related Art

A substrate structure for an integrated circuit package has been described in the commonly-assigned U.S. Pat. No. 6,489,572. As shown in FIG. 1, the substrate structure includes a plurality of metal sheets 10 arranged in an array and an encapsulant 16. Each metal sheet 10 has a first surface 12 and a second surface 14. The encapsulant 16 encapsulates each metal sheet 10 to form a substrate with the first surfaces 12 and the second surfaces 14 of the metal sheets 10 exposed from the encapsulant 16. The exposed first surfaces and second surfaces form signal input terminals to be connected to an integrated circuit and signal output terminals to be connected to a printed circuit board, respectively.

However, the above-mentioned structure still has the following drawbacks.

1. Since the metal sheets 10 cannot be made thick even by pressing or etching, when the metal sheets 10 are packaged, disadvantageous factors (e.g., heat and moisture) will enter the integrated circuit, thereby influencing the electrical property of the integrated circuit and reducing the product reliability.

2. Since the metal sheets 10 are thin, the solder tin cannot climb to the lateral sides of the metal sheets 10 during the SMT process. Thus, the stability of mounting the package body to the printed circuit board is also influenced.

### SUMMARY OF THE INVENTION

An object of the invention is to provide a substrate structure for an integrated circuit package with increased thickness of the combined metal sheets of the substrate and enhanced package reliability, and a method for manufacturing the same.

Another object of the invention is to provide a substrate structure for an integrated circuit package, in which the solder tin may climb higher during the SMT process so as to enhance the stability of mounting the substrate to the printed circuit board, and a method for manufacturing the same.

To achieve the above-mentioned objects, the invention provides a substrate structure for an integrated circuit package to be electrically connected to a printed circuit board. The substrate structure includes a plurality of lower metal sheets arranged in an array, a plurality of upper metal sheets arranged in an array, and an encapsulant for encapsulating the lower metal sheets and the upper metal sheets. Each of the lower metal sheets has an upper surface and a lower surface. Each of the upper metal sheets has an upper surface and a lower surface, and the lower surfaces of the upper metal sheets are stacked on the upper surfaces of the lower metal sheets. The upper surfaces of the upper metal sheets are exposed from the encapsulant, and the lower surfaces of the lower metal sheets are exposed from the encapsulant and electrically connected to the printed circuit board.

### BRIEF DESCRIPTION OF THE DRAWINGS

FIG. 1 is a schematic illustration showing a conventional package structure for an image sensor.

FIG. 2 is a cross-sectional view showing a substrate structure for an integrated circuit package of the invention.

FIG. 3 is a first schematic illustration showing a method for manufacturing a substrate for an integrated circuit package of the invention.

FIG. 4 is a second schematic illustration showing the method for manufacturing the substrate for the integrated circuit package of the invention.

FIG. 5 is a cross-sectional view showing the lower metal sheets 20 stacked on the upper metal sheets 26 of the invention.

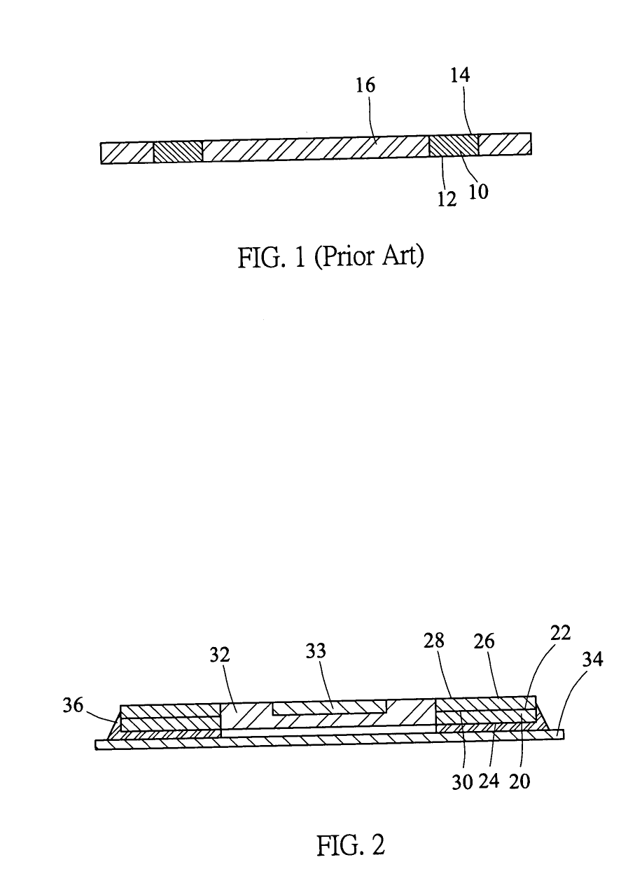

### DETAILED DESCRIPTION OF THE INVENTION

Referring to FIG. 2, a substrate structure for an integrated circuit package of the invention includes a plurality of lower metal sheets 20 arranged in an array, a plurality of upper metal sheets 26 arranged in an array, and an encapsulant 32.

Each lower metal sheet 20 has an upper surface 22 and a lower surface 24.

Each upper metal sheet 26 has an upper surface 28 and a lower surface 30. The lower surfaces 30 of the upper metal sheets 26 are stacked on the upper surfaces 22 of the lower metal sheets 20, respectively. A middle board 33 flush with the upper metal sheets 26 is arranged among the upper metal sheets 26, wherein an integrated circuit may be arranged on the middle board 33.

The encapsulant 32 encapsulates the lower metal sheets 20, the upper metal sheets 26 and the middle board 33 with the upper surfaces 28 of the upper metal sheets 26 and an upper surface of the middle board 33 exposed from the encapsulant 32 and with the lower surfaces 24 of the lower metal sheets 20 exposed from the encapsulant 32. The exposed lower surfaces 24 of the lower metal sheets 20 are to be electrically connected to a printed circuit board 34 so that signals from the integrated circuit may be transferred to the printed circuit board.

When the substrate structure of the invention is used for packaging an integrated circuit, since the substrate is composed of upper and lower metal sheets 26 and 20, the thickness of the substrate is larger. Thus, it is possible to effectively prevent disadvantageous factors (e.g., heat and moisture) from influencing the electrical property of the integrated circuit, and better reliability of the package body may be obtained. In addition, when the packaged body is to be mounted to the printed circuit board 34 during the SMT process, the solder tin 36 may climb to the upper metal sheets 26 of the substrate, and larger adhesive forces may be obtained.

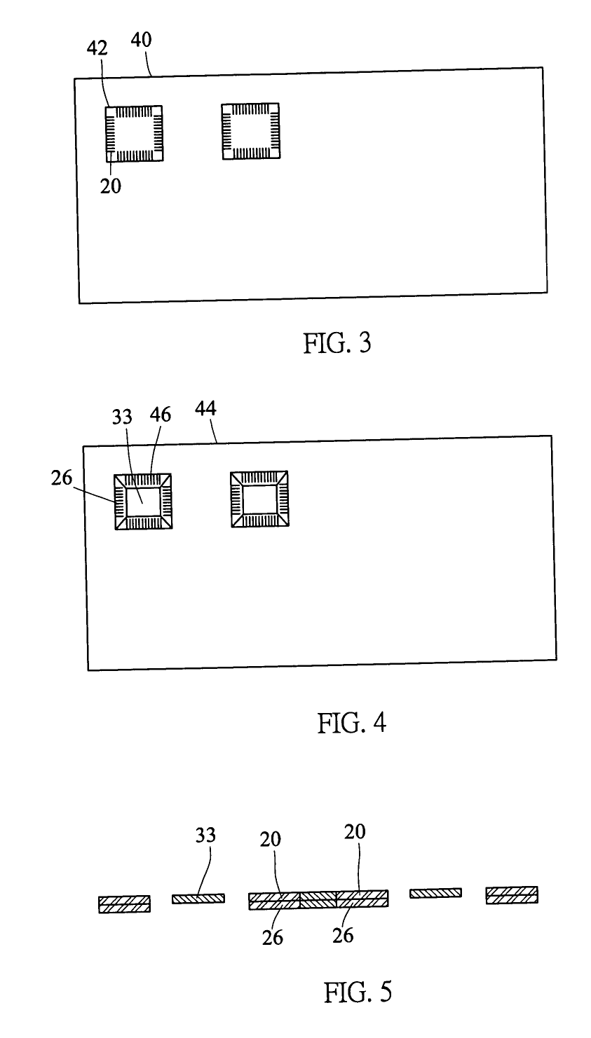

As shown in FIGS. 3 to 5, a lower metal board 40 is pressed or etched to form several lower metal sheet sets 42 in this embodiment. Each lower metal sheet set 42 is formed with a plurality of lower metal sheets 20 arranged in an array. An upper metal board 44 is pressed or etched to form several upper metal sheet sets 46. Each upper metal sheet set 46 is formed with a plurality of upper metal sheets 26 arranged in an array and a middle board 33 among the upper metal sheets 26. The upper metal board 44 is then stacked on the lower metal board 40, as shown in FIG. 2. Then, the upper and lower metal sheets 26 and 20 are encapsulated by industrial plastic material by way of injection molding. The industrial plastic material is formed into the encapsulant 32 with the upper surfaces 28 of the upper metal sheets 26, the middle board 33, and the lower surfaces 24 of the lower metal sheets 20 exposed from the encapsulant 32. Then, the stacked lower metal sheets 20 and the upper metal sheets 26 are cut to form the substrates of the invention.

Thus, the method for manufacturing the substrate structure of the invention includes the steps of:
providing a plurality of lower metal sheets 20 arranged in an array, each lower metal sheet 20 having an upper surface 22 and a lower surface 24;
providing a plurality of upper metal sheets 26 arranged in an array, each upper metal sheet 26 having an upper surface 28 and a lower surface 30, the lower surfaces 30 being stacked on the corresponding upper surfaces 22 of the lower metal sheets 20, respectively, and providing a middle board 33 flush with and among the upper metal sheets 26; and
providing an encapsulant 32 formed of industrial plastic material by way of injection molding to encapsulate the lower metal sheets 20, the upper metal sheets 26 and the middle board 33 with the upper surfaces 28 of the upper metal sheets 26 and the upper surface of the middle board 33 exposed from the encapsulant 32, and with the lower surfaces 24 of the lower metal sheets 20 exposed from the encapsulant 32. Thus, the substrate structure of the invention may be manufactured.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. A substrate structure for an integrated circuit package to be electrically connected to a printed circuit board, the substrate structure comprising:
a plurality of lower metal sheets arranged in an array, each of the lower metal sheets having an upper surface and a lower surface;
a plurality of upper metal sheets arranged in an array, each of the upper metal sheets having an upper surface and a lower surface, the lower surfaces of the upper metal sheets being stacked on the upper surfaces of the lower metal sheets; and
an encapsulant for encapsulating the lower metal sheets and the upper metal sheets, wherein the upper surfaces of the upper metal sheets are exposed from the encapsulant, and the lower surfaces of the lower metal sheets are exposed from the encapsulant and electrically connected to the printed circuit board.

2. The substrate structure according to claim 1, further comprising a middle board arranged among and flush with the upper metal sheets, and the integrated circuit package being mounted to the middle board.

3. The substrate structure according to claim 1, wherein the encapsulant is made of plastic material.

4. A method for manufacturing a substrate structure for an integrated circuit package, comprising the steps of:
providing a plurality of lower metal sheets arranged in an array, each of the lower metal sheets having an upper surface and a lower surface;
providing a plurality of upper metal sheets arranged in an array, each of the upper metal sheets having an upper surface and a lower surface, the lower surfaces of the upper metal sheets being stacked on the upper surfaces of the lower metal sheets; and
providing an encapsulant for encapsulating the lower metal sheets and the upper metal sheets, wherein the upper surfaces of the upper metal sheets are exposed from the encapsulant, and the lower surfaces of the lower metal sheets are exposed from the encapsulant and electrically connected to a printed circuit board.

5. The method according to claim 1, further comprising:
arranging a middle board among and flush with the upper metal sheets, and the integrated circuit package being mounted to the middle board.

6. The method according to claim 1, wherein the encapsulant is made of industrial plastic material by way of injection molding.
